(19) United States
(12) Patent Application Publication
(10) Pub. No.: US 2023/0044657 A1
(43) Pub. Date: Feb. 9, 2023

(54) Surface Mount Devices Containing a Plurality of Pixels and Sub-Pixels and Providing Off-Axis Color Correction for Video Wall Displays

(71) Applicant: H2VR HoldCo, Inc., Walnut, CA (US)

(72) Inventor: Jeremy Hochman, Walnut, CA (US)

(21) Appl. No.: 17/970,624

(22) Filed: Oct. 21, 2022

Related U.S. Application Data
(63) Continuation-in-part of application No. PCT/US2021/028310, filed on Apr. 21, 2021.
(60) Provisional application No. 63/012,984, filed on Apr. 21, 2020.
(60) Provisional application No. 63/270,553, filed on Oct. 21, 2021.

(51) Int. Cl. H01L 27/15; H01L 27/32; H01L 25/075

(52) U.S. Cl. CPC H01L 27/156; H01L 27/3213; H01L 27/3216; H01L 25/0753

(57) ABSTRACT

Light-emitting surface mount devices comprised of an array of emitters forming multi-color and white pixels wherein the multi-color pixels have at least substantially the same overall pixel height and width as the white pixels in the array and methods of making same are disclosed. Visual uniformity is enhanced thereby. Light-emitting arrays of color pixel groups with adjacent pixel groups arranged relative to one another, such as by using different color orders, color orientations or color alignments, so that the off-axis color skew is more dispersed between many viewing angles and thus reduced or even eliminated when large groups of emitters are simultaneously observed from a specific viewing angle,

### RELATED APPLICATION DATA

This application is a continuation-in-part of PCT Application No. PCT/US2021/028310, filed Apr. 21, 2021, and titled “Surface Mount Device Containing a Plurality of Pixels and Sub-Pixels”, which application claims priority to U.S. Provisional Application No. 63/012,984, filed Apr. 21, 2020, titled “Surface Mount Device (SMD) Containing a Plurality of Pixels and Sub-Pixels of at least Red, Green, Blue and White”. This application also claims priority to U.S. Provisional Application No. 63/270,553, filed Oct. 21, 2021, and titled “Surface Mount Devices Providing Off-Axis Color Correction For Dynamic Image Capture Of Video Wall Displays.” This application is also related to PCT Application No. PCT/US2021/056123, filed Oct. 21, 2021, and titled “Off-Axis Color Correction for Dynamic Image Capture of Video Wall Displays”. Each of the foregoing applications is incorporated by reference herein in its entirety.

### FIELD OF THE DISCLOSURE

The present disclosure generally relates to the field of light-emitting device packages. In particular, the present disclosure is directed to surface mount devices (SMD) containing a plurality of pixels and sub-pixels of at least red, green, blue, and white, and other light emitting arrays providing off-axis color correction for video wall displays.

### BACKGROUND

Video displays that use light-emitting diodes (LEDs) as their light source have significant challenges as resolutions increase and the spacing between pixels is reduced. In addition, not only are there physical challenges because of the reduced spacing, the small spacing also creates an issue when modular tiles are abutted next to one another—there is a high likelihood of physical damage during installation. The robustness and repairability of a display module are important, however these two attributes are often trade-offs for each other.

In order to make a display ultimately repairable, each circuit board with an array of LEDs is made up of single pixel (or even sub-pixel) SMD LED packages. In one example, in an array of 100×100 pixels on a circuit board, 100×100 RGB SMD LEDs can be utilized. This allows a single damaged pixel to be replaced without affecting the rest of the array. In an extreme example, assuming each pixel is made of at least one each of red, green, and blue, 300×300 individual sub-pixel SMDs can be used for the array. If even a single sub-pixel is damaged, it can be replaced without affecting the others. These two described methodologies have been used for over 20 years in the LED industry.

In order to make a display as robust as possible, it is typical to see a potting compound user over the top of an LED array. The LED array can be made of individual SMD pixels as in the previous example, or it can be a chip-on-board (COB) process in which the diode chips are bonded directly to a circuit board as shown in FIG. 7. In both of these instances, a self-leveling epoxy or silicone can be put over the entire array to make it solid and robust. This achieves a very durable front face to the array capable of withstanding reasonable impact and scratches. The corners and edges of the array, however, are still susceptible to impact, and if impact occurs, the mechanical characteristics of the potting material usually damage a cluster of RGB pixels rather than a single pixel. Further, because of the nature of the potting material being of cured adhesive, it is generally not possible (or not reasonably commercially possibly) to repair the damaged pixel. Further, if a pixel can in fact be repaired, the potting material cannot be re-applied in a way that is not obviously re-applied (i.e. the repaired surface looks different from the rest of the array). This means that if a single pixel is damaged in the 100×100 pixel array, the entire array becomes unusable. This further means that just one damaged pixel requires 9,999 good pixels to be thrown away. This is incredibly inefficient, wasteful, and harmful for the environment. Another downside to these traditional techniques is that when a plurality of arrays are placed together to form a large display, the edges of the abutting arrays can be quite noticeable, similar to grout lines in architectural/building material tiles.

Another obstacle in creating displays in which the pixels are extremely close together is that the amount of solder junctions to fix the required number of red, green, blue (and possibly white or other sub-pixel colors) sub-pixels to the PCB in an array becomes too time-intensive for even the fastest automated machinery. In addition, when screen resolution has a smaller pixel pitch than the acuity of human vision, it can also be unnecessary to have all of the sub-pixel elements in every single pixel location. This can be assimilated to half-tone printing in which sub-pixel colors are spaced in a known pattern to create a perceivable image when viewed from a certain distance. Many LCD or OLED monitors arrange sub-pixels in non-linear arrays, or add another color to help the special arrangement of the pixel or to help with the achievable color gamut of the display.

Video walls comprised of an array of LED display tiles and displaying dynamic images are with increasing frequency used as backgrounds for movie sets and broadcast video scenes. As one example, on movie sets, instead of the actors performing in front of a green screen with the background later added by CGI techniques, the actors perform in front of a video wall dynamically displaying the desired background scene, which is then captured along with the actors by the camera. In another example, for broadcast video, in a news broadcast the presenter is positioned in front of a video wall and the video camera captures both the presenter and images displayed on the video wall behind the presenter. Using this technique, the camera capturing the scene is capturing not only the live action or performance in front of the video wall, but also images concurrently displayed on the video wall behind the live action. The display on the video wall is thus an active and changing part of the scene being captured by the camera. Because the video camera is actually capturing a scene displayed on a video display wall, there are a number of challenges to be overcome so that the image captured by the video camera does not appear with artifacts or other distortions that would adversely impact the quality of the captured image.

One problem to be overcome is color distortions or variations that occur when the camera captures an image produced by an array of LED pixels at varying viewing angles. LED tiles have different color performance when viewed off-axis from perpendicular. This is due to the diode arrangement, in addition to physicalities of the pixel construction. Some pixels have RGB sub-pixel color components arranged in a vertical line, while others can be arranged in a triangle. The internal arrangement of the sub-pixel color components varies from manufacturer to manufacturer due to electronic or manufacturing constraints, particularly as parts are increasingly miniaturized. In addition to the non-uniformity of a single pixel, when a plurality of LEDs are placed on a circuit board to make up a display panel, it is possible for the physical structure of neighboring pixels to occlude each other and block certain portions of the pixel from being fully visible. All of these variations lead to a different appearance at different view angles. Depending on the view angle, the variations may be minor to dramatic as illustrated by FIG. 16 (which are color images as filed).

The lack of uniformity of a display viewed from different angles can be quite unattractive for critical content, such as flat white fields, or corporate logos that must remain the “same” color or shade no matter the viewing angle. The amount of variation from the standard or desired color—in this case a blank screen presenting the D65 illuminant—can vary based on the amount of variation from the perpendicular view angle (Position 2). Note that FIG. 16 presents a simplified depiction in that the only variation shown between Positions 1, 2 and 3 is along the horizontal axis. The same type of color variation occurs in the same manner when the view angle deviates in the vertical direction above or below the display centerline. The details shown for Positions 1, 2 and 3 also represent the view over a fixed field of view at each position. While in these simplified, printed illustrations the variations may not appear large, in practice, when the display wall presents an image with complex color variations and movement, the distortions in color can be very dramatic at certain view angles dependent on the physical configuration of the LED tiles and video wall.

A contributing factor in the color skew discussed above is the presence of small patterns inside the emitters themselves. These internal patterns are created by internal components of the emitters, such as bonding pads and electrodes. As a result, if the dispersion of light from the emitters is not perfectly uniform, it becomes skewed off axis. Another technical challenge in attempting to address color skew is the fact that with current high resolution screens, the PCB routing is extremely difficult and time consuming, which is a significant technical barrier to alternative emitter arrangements that might lessen off-axis color skew. For example, current high resolution screens typically have emitters arranged in very regular grids and repeating patterns. Most commonly seen are uniform rows of red emitters followed by a uniform row of green emitters and then a uniform row of blue emitters. This pattern typically repeats across the entire display surface. Altering this regular, repeating arrangement with conventional manufacturing techniques adds tremendous technical challenges, complexity and cost to the PCBs in order to make proper connections to driver chips, power rails, etc.

One possible solution for correcting such off-axis color distortions in captured images is described in Applicant's co-pending PCT Application No. PCT/US21/56123, filed Oct. 21, 2021, and titled “Off-Axis Color Correction in Dynamic Image Capture of Video Wall Displays,” which is incorporated herein by reference. The solution described in this incorporated pending application involves application of software-implemented color correction layer to the cameral field of view region on the display surface in order to reduce or eliminate color distortions in the displayed image.

Another solution is provided in the present disclosure in the form of SMD devices arranged to avoid or minimize the need for color correction upon image capture. The present solution also addresses and solves the technical challenges that arise in conventional devices from the use of emitters arranged in non-linear row patterns.

In light of these challenges, there remains a need in the art for readily configurable and repairable modular solutions to creation of LED tiles for creation of tiled LED displays and large video wall-type LED displays, in particular.

### SUMMARY OF THE DISCLOSURE

In one implementation, the present disclosure is directed to a light-emitting surface mount device, which includes a micro-array of self-emitting pixels including at least one white emitter with a height and width sized at least substantially equal to a combined height and width of a multi-color set of emitters of a neighboring pixel, wherein the micro-array comprises at least 2 horizontal and 2 vertical pixels.

In another implementation, the present disclosure is directed to a method of making a light-emitting micro-array, which includes configuring plural multi-color pixels, each pixel comprising plural different color emitters and having an overall height and width; surface mounting the multi-color pixels to a micro-array substrate; configuring plural white emitters, each the white emitter having an overall height and width substantially the same as the height and width of each the multi-color pixel; and surface mounting the white emitters to the micro-array substrate adjacent the multi-color pixels to form a micro-array of alternating multi-color pixels and white pixels.

In yet another implementation, the present disclosure is directed to a light-emitting device, which includes an array of self-emitting pixels, wherein each pixel of the array comprises the same plural different color light emitters; and the different color light emitters of each pixel of the array are arranged in at least one of a different order, different orientation or different alignment relative to the different color light emitters in an at least two adjacent pixels of the array.

In still another implementation, the present disclosure is directed to a light-emitting device configured as a surface mount device providing reduced off-axis color skew from specific viewing angles. The device includes a 2×2 pixel micro-array with one row consisting of a first pixel formed of an ordered sequence of a red LED, a green LED and a blue LED and a second pixel formed of a single white LED, and with another row consisting of a first pixel formed of a single white LED and a second pixel formed of an ordered sequence of a blue LED, a green LED and a red LED.

### BRIEF DESCRIPTION OF THE DRAWINGS

For the purpose of illustrating the disclosure, the drawings show aspects of one or more embodiments of the disclosure. However, it should be understood that the present disclosure is not limited to the precise arrangements and instrumentalities shown in the drawings, wherein:

FIG. 1 is a schematic depiction of a first embodiment of LED micro-array according to the present disclosure.

FIG. 2 is a schematic depiction of a second embodiment of LED micro-array according to the present disclosure.

FIG. 3 is a schematic depiction of a third embodiment of LED micro-array according to the present disclosure.

FIG. 4 is a schematic depiction of a fourth embodiment of LED micro-array according to the present disclosure.

FIG. 5 is a schematic depiction of a portion of an LED display tile utilizing an embodiment of a micro-array as depicted in FIG. 1.

FIG. 6 is a schematic depiction of a fifth embodiment of LED micro-array according to the present disclosure.

FIG. 7 is a schematic depiction of a sixth embodiment of LED micro-array according to the present disclosure.

FIG. 8 is a schematic depiction of a portion of an LED display tile utilizing an embodiment of a micro-array as depicted in FIG. 6.

FIG. 9 is a partial schematic plan view of an LED tile according to an embodiment of the present disclosure.

FIG. 10 is a schematic plan view of a micro-array according to an embodiment of the present disclosure.

FIG. 11 is a schematic cross-sectional view of a micro-array according to an embodiment of the present disclosure.

FIG. 12 is a schematic cross-sectional view of a micro-array according to another embodiment of the present disclosure.

FIG. 13 is a diagram illustrating visual acuity in average adults as applied in embodiments of the present disclosure.

FIG. 14 is a front view of an LED display according to the present disclosure utilizing tiles made up of micro-arrays as disclosed herein.

FIG. 15 is a partial schematic plan view of an example of a prior art LED tile.

FIG. 16 depicts a simplified example of color distortions that can arise from off-axis viewing of an LED video wall.

### DETAILED DESCRIPTION

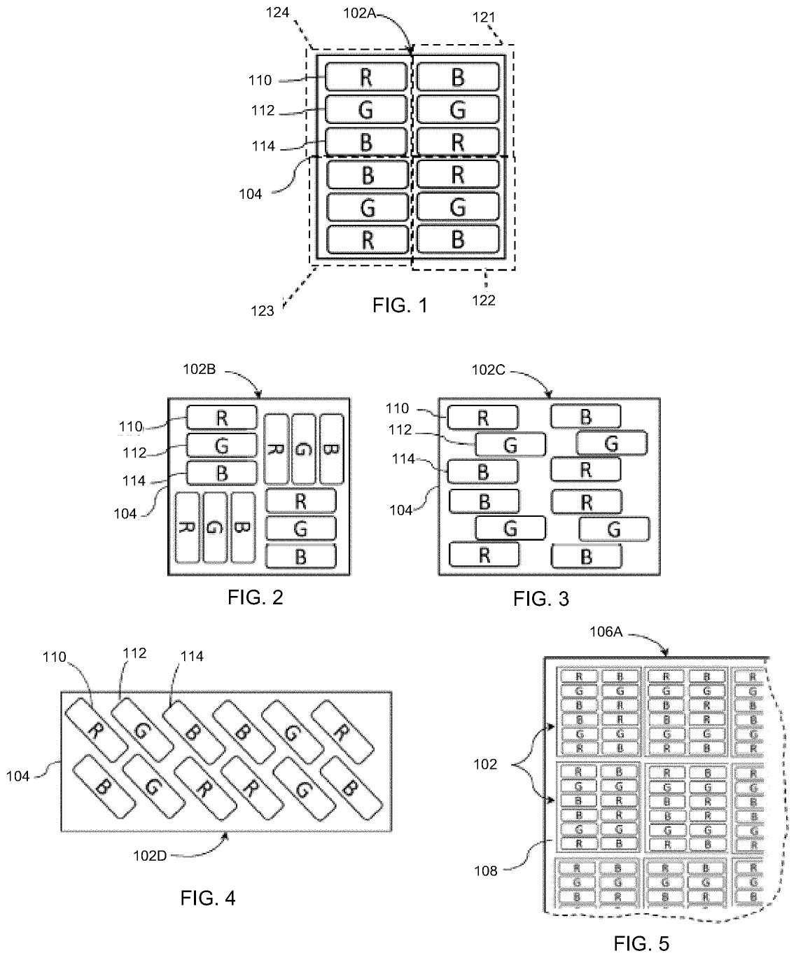

Embodiments disclosed herein utilize surface mount devices (SMD) configured with micro-arrays of alternatingly arranged RGB(N) (red/green/blue/(other possible color) or RGB(N)+W (red/green/blue/(other possible color)+white) pixels to provide an off-axis color correction solution to the problem described above as well as to provide other SMD features and advantages as described hereinafter. Embodiments of the present disclosure utilize micro-arrays of emitters wherein the emitters are arranged in patterns to minimize or eliminate off-axis color distortions when images presented on a display wall comprised of tiles made up of the micro-arrays are captured with an image-capture device at varying angles. Details of various embodiments of an individual micro-array 102A-F are shown in FIGS. 1-4, 6 and 7. Note that in the following description, reference numeral 102 is used to refer to all of micro-arrays 102A-F collectively with respect to features or configurations that are common among all embodiments.

As shown in FIG. 1, micro-array substrate 104, has mounted thereon twelve (12) LEDs forming four pixels, in other words forming a 2×2 pixel array making up a single micro-array 102A. In this example, each of the pixels comprise one each of red LED 110, green LED 112, and blue LED 114. The pixels, however, are formed with the different color LEDs arranged in different orders as shown in order to provide more uniform color characteristics from a wide range of image capture/viewing angles. FIGS. 2, 3 and 4 illustrate alternative embodiments in which micro-arrays 102B, 102C and 102D are fabricated substantially as micro-array 102A, but with different arrangements of the different color LEDs 110, 112 and 114 so that emitters are positioned at a plurality of angular orientations with respect to one another across the display surface in order to distribute the non-uniform color characteristics in less perceptible patterns. For example, different orientations are illustrated in FIG. 2, different alignments are illustrated in FIG. 3, and different orders are illustrated in FIG. 4.

As mentioned above, in conventional LED-based display devices, internal components create non-uniform dispersion of emitted light causing off-axis color skew. Not only is there color skew for this reason, the color skew can be different for each of the red, green and blue emitters, further complicating potential solutions. Thus, in embodiments of the present disclosure, the fact of the off-axis color skew on an emitter-by-emitter basis is accepted and no attempt is made to create perfectly uniform emitters individually. Instead, the present disclosure arranges adjacent pixel groups relative to one another, such as by using different color orders, color orientations or color alignments, so that the off-axis color skew is more dispersed between many viewing angles and thus reduced or even eliminated when large groups of emitters are simultaneously observed from a specific viewing angle (as is the typical viewing modality both for human viewers and image capture devices). While increasing the number of individual emitters at different relative angles to one another would further reduce off-axis color skew, it has been determined that just two or four relative rotations of emitters or small groups of emitters are sufficient to “mix” together the skews of the individual emitters to achieve improved results in the form of reduced or eliminated color skew. For example, by flip-flopping the RGB/BGR in a checkerboard, that arrangement can provide a satisfactory horizontal and vertical appearance, with a pinwheel arrangement on top of that wherein emitters are further rotated 90 degrees and flip-flopped, excellent results are achieved in terms of color skew or distortion elimination at off-axis viewing angles.

With reference again to FIG. 1, relative positions of pixels or pixel groups with respect to each other may be described. In the embodiment shown in FIG. 1, each pixel or pixel group is identified by a dashed box, labeled 121, 122, 123 and 124. Each pixel or pixel group is made up of a red, a green and a blue LED, respectively, 110, 112, and 114, arranged in different orders. As shown therein, pixel group 123 has as adjacent pixel groups, horizontally adjacent pixel group 122, vertically adjacent pixel group 124 and diagonally adjacent pixel group 121. In various alternative embodiments disclosed herein, the arrays of pixels have pixel groups (or single white pixels) arranged in this same manner. The meaning of the terms horizontally adjacent, vertically adjacent and diagonally adjacent are thus used throughout as defined in this paragraph.

In some embodiments, each of LEDs 110, 112, 114 are direct bonded to substrate 104. Prepackaging of micro-arrays 102 into a single package as disclosed herein provides further advantages in fabrication by reducing pick-and-place times and simplifying complex printed circuit board (PCB) designs so as to achieve complex pixel arrangements, but with standardly formatted micro-arrays, which may be uniformly placed and connected.

FIG. 5 illustrates a portion of tile 106A according to one embodiment of the present disclosure, comprising an array of micro-arrays 102 mounted on an appropriate primary tile substrate 108, which may be, for example, a printed circuit board (PCB) or other appropriate substrate. Examples of suitable substrates for primary tile substrate 108 include standard PCB material such as FR4, flexible circuit material or foil, conductive fabric, conductive glass, or metal circuit boards. Tile 106A may extend in the X and Y directions as needed to form a desired tile size for a particular application. For example, the tile size may comprise a 10×10 array of micro-arrays 102, or a 100×100 array, or any size in-between, smaller or larger. Note that for micro-arrays 102 positioned on the edge of the larger tile array, the spacing to the edge of tile substrate 108 will be half of the spacing between adjacent micro-arrays 102 so as to provide a visually continuous appearance when multiple tiles 106A are abutted to form a video panel.

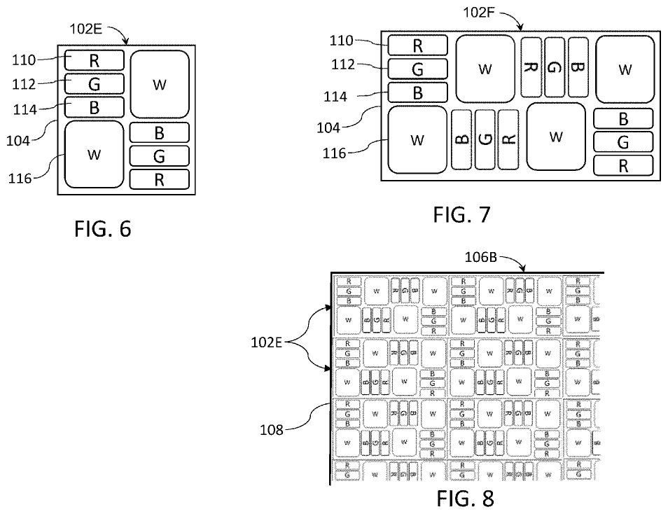

In further alternative embodiments, as shown in FIGS. 6 and 7, micro-array substrate 104 has mounted thereon eight LEDs forming four pixels, in other words forming a 2×2 pixel array making up a single micro-array 102E or 102F. In these examples, two pixels comprise one each of red LED 110, green LED 112, blue LED 114, and two pixels comprise a single white LED 116. As with the embodiments described above, micro-arrays 102E and 102F are formed with the different color pixels arranged in different orders as shown in FIGS. 6 and 7 so as to provide more uniform color characteristics from a wide range of image capture/viewing angles. FIGS. 6 and 7 illustrate alternative embodiments in which micro-arrays 102E and 102F are fabricated substantially the same, but with different orientations of the different color LEDs 110, 112 and 114 again arranged in flip-flopped and rotated orientations as described above.

With respect to embodiments shown in FIGS. 6 and 7, each of LEDs 110, 112, 114 and 116 may be direct bonded to substrate 104. In another embodiment, RGB LEDs 110, 112 and 114 are direct bonded to substrate 104, but W LED 116 is formed on a separate substrate and then bonded to substrate 104. For example, W LED 116 may be formed itself as an SMD package with a small blue emitter (die) to excite an illuminating substance, such as phosphor, which covers the entire, or virtually the entire, designated area of W LED 116 in order to provide an appropriately sized white illumination area as discussed below. In yet another embodiment, RGB LEDs 110, 112 and 114 are themselves surface mounted to a separate substrate, which is then bonded to substrate 104. The separate substrate may comprise a standard PCB itself made from FR4 material or similar, or may be a wafer substrate material such as sapphire, silicon, silicon carbide, or gallium nitride. As is generally known in the art, substrates described herein may comprise multiple layers, including for example a ceramic layer, a metal interconnect layer and a lower layer comprising elements such as a thermal pad and cathode.

In another advantage of embodiments disclosed herein, the micro-arrays 102 may be individually encapsulated with a light transmissive protective encapsulation layer over the LEDs. Examples of materials for the encapsulation layer include silicone or epoxy resin/potting compounds or conformal coatings such as parylene, paraxylene, acrylic, silicone, polyurethane or lacquer. Additionally, lenses, for example epoxy or silicone lenses, may be optionally disposed over the entire micro-array or over individual or groups of emitters.

Embodiments described herein easily lend themselves to different types of surface-mount packaging as may be best suited to particular applications. For example, embodiments disclosed herein may be provided as ball grid array (BGA) packages, various types of flat no-leads packages such as quad-flat no-leads (QFN) packages, or various chip carrier packages such as plastic-leaded chip carrier (PLCC) packages.

One feature of embodiments disclosed herein is that the size, i.e. overall profile (height and width) dimensions of white LED 116 are at least substantially the same as the combined size (combined height and width) of RGB LEDs 110, 112 and 114 together so as to provide a smooth and consistent visual appearance in all illumination conditions. This means that in various embodiments the combined height and combined width of the multi-color pixel and the height and width of the white pixel, if not identical, vary from one another by not more than about 1% to about 20%. (Within plus/minus 0% would be identical in size). In some embodiments, the combined height and combined width of the multi-color pixel is within about 5% to about 10% of the height and width of the white pixel.

Spacing and sizing of micro-arrays 102 can be based on visual acuity of an observer. Typical visual acuity for adults is 1 arc-minute in size, or approximately 2 pixels per degree. In general, a micro-array size should be selected such that a viewer would not perceive the boundaries of the micro-array. Parameters to be considered in sizing micro-arrays 102 include an array size which is large enough to yield improvements in durability and robustness, yet small enough for repairability to the array on a PCB.

The distance between the viewer and the display will have a direct correlation to an ideal array size, however generally the pixel pitch is also chosen based on this distance. In one example, a 100×100 pixel array may be formed according to the present disclosure using an array of micro-arrays 102 with sub-pixels and pixels in as small as a 2×2 array and large as a 16×16 array such that the micro-array size need not exceed 5 mm×5 mm. In the case of a 2×2 micro-array, the footprint of the SMD is four times more robust than a single RGB SMD pixel, yet it is small enough such that it can be replaced to repair the array without being commercially unreasonable. And it is also small enough to be within visual acuity such that an observer will not be able to see a physical pattern or break-up in a very large array (in other words, the “texture” of the front of a very large display will appear uniform).

In one example, the dimensions of micro-array 102 may be approximately 5 mm or less by 5 mm or less. With a 5×5 mm micro-array, individual pixel size may be in the range of about 2×2 mm to about 2.4×2.4 mm in some embodiments. As illustrative examples, white LED 116 may comprise a 6504 Kelvin or 2700 Kelvin LED. A further feature of embodiments disclosed herein, is that each micro-array 102 may be individually encapsulated. Thus, when an LED fails on one micro-array, only that specific micro-array need be replaced. The replacement micro-array then provides a more uniform appearance with the existing micro-arrays because any variations in encapsulation layers fall within each of the micro-arrays. Also, a single LED failure only requires replacement of a single micro-array, for example just eight LEDs in one embodiment, thus providing much more efficiency and less waste compared to prior designs.

FIG. 8 illustrates a portion of tile 106B according to one embodiment of the present disclosure, comprising an array of micro-arrays 102E mounted on an appropriate primary tile substrate 108, which may be, for example, a printed circuit board (PCB) or other appropriate substrate. Examples of suitable substrates for primary tile substrate 108 include standard PCB material such as FR4, flexible circuit material or foil, conductive fabric, conductive glass, or metal circuit boards. Tile 106B may extend in the X and Y directions as needed to form a desired tile size for a particular application. For example, the tile size may comprise a 10×10 array of micro-arrays 102, or a 100×100 array, or any size in-between, smaller or larger. Note that for micro-arrays 102E positioned on the edge of the larger tile array 106B, the spacing to the edge of tile substrate 108 will be half of the spacing between adjacent micro-arrays 102E so as to provide a visually continuous appearance when multiple tiles are abutted to form a video panel.

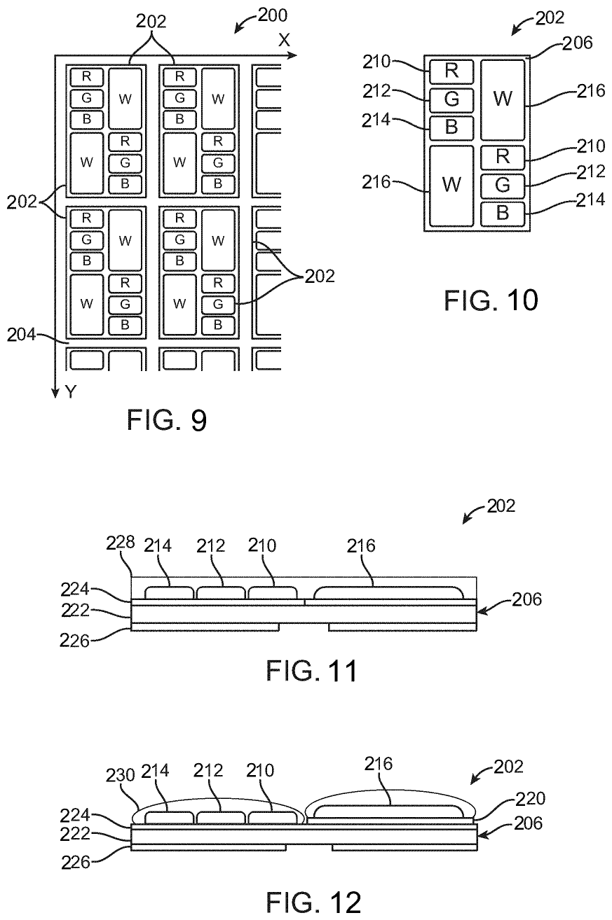

FIGS. 9-14 illustrate further SMD-related features that may be incorporated into light emitting devices providing off-axis color correction in video displays. For example, FIG. 9 illustrates a portion of tile 200 according to one embodiment of the present disclosure, comprising an array of micro-arrays 202 mounted on an appropriate primary tile substrate 204, which may be, for example, a printed circuit board (PCB) or other appropriate substrate. Examples of suitable substrates for primary tile substrate 204 include standard PCB material such as FR4, flexible circuit material or foil, conductive fabric, conductive glass, or metal circuit boards. As indicated by arrows X and Y along the edges of tile substrate 204, tile 200 may extend in each X, Y direction as needed to form a desired tile size for a particular application. For example, the tile size may comprise a 10×10 array of micro-arrays 202, or a 100×100 array, or any size in-between, smaller or larger. Note that for micro-arrays 202 positioned on the edge of the larger tile array 200, the spacing to the edge of tile substrate 204 will be half of the spacing between adjacent micro-arrays 202 so as to provide a visually continuous appearance when multiple tiles 200 are abutted to form a video panel. Further spacing considerations are discussed below.

Details of an embodiment of an individual SMD micro-array 202 are shown in FIGS. 10, 11 and 12 As shown FIG. 10, micro-array substrate 206 has mounted thereon eight LEDs forming four pixels, in other words forming a 2×2 pixel array making up a single micro-array 202. In this example, two pixels comprise one each of red LED 210, green LED 212, blue LED 214, and two pixels comprise a single white LED 216. In one embodiment, each of LEDs 210, 212, 214 and 216 are direct bonded to substrate 206 as shown in FIG. 11. In another embodiment, RGB LEDs 210, 212 and 214 are direct bonded to substrate 206, but W LED 216 is formed on a separate substrate 220 and then bonded to substrate 206 as shown in FIG. 12. For example, W LED 216 may be formed itself as an SMD package with a small blue emitter (die) to excite an illuminating substance, such as phosphor, which covers the entire or virtually the entire designated area of LED 216 in order to provide an appropriately sized white illumination area as discussed below. In yet another embodiment, RGB LEDs 210, 212 and 214 are themselves surface mounted to a separate substrate, which is then bonded to substrate 206. Substrate 206 may comprise a standard PCB itself made from FR4 material or similar, or may be a wafer substrate material such as sapphire, silicon, silicon carbide, or gallium nitride. As is generally known in the art, substrate 206 may comprise multiple layers, including for example ceramic layer 222, metal interconnect layer 224 and a lower layer 226 comprising elements such as a thermal pad and cathode.

In another advantage of embodiments disclosed herein, the micro-arrays may be individually encapsulated with a light transmissive protective encapsulation layer 228 over the LEDs, as shown in FIG. 11. Examples of materials for encapsulation layer 228 include silicone or epoxy resin/potting compounds or conformal coatings such as parylene, paraxylene, acrylic, silicone, polyurethane or lacquer. Additionally, lenses 230, for example epoxy or silicone lenses, may be optionally disposed over the entire micro-array or over individual or groups of emitters as shown in FIG. 12. In some embodiments, encapsulation layer 228 may be used together with lenses 230.

Embodiments described herein easily lend themselves to different types of surface-mount packaging as may be best suited to particular applications. For example, embodiments disclosed herein may be provided as ball grid array (BGA) packages, various types of flat no-leads packages such as quad-flat no-leads (QFN) packages, or various chip carrier packages such as plastic-leaded chip carrier (PLCC) packages.

One feature of embodiments disclosed herein is that the size, i.e. overall profile (height and width) dimensions of white LED 216 are at least substantially the same as the combined size (combined height and width) of RGB LEDs 210, 212 and 214 together so as to provide a smooth and consistent visual appearance in all illumination conditions. This means that in various embodiments the combined height and combined width of the multi-color pixel and the height and width of the white pixel, if not identical, vary from one another by not more than about 1% to about 20%. (Within plus/minus 0% would be identical in size). In some embodiments, the combined height and combined width of the multi-color pixel is within about 5% to about 10% of the height and width of the white pixel.

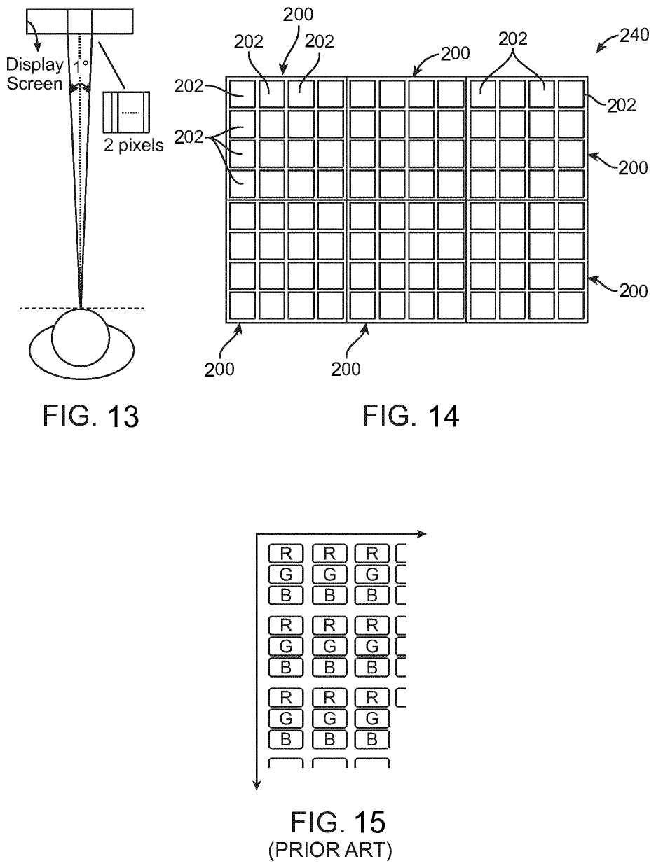

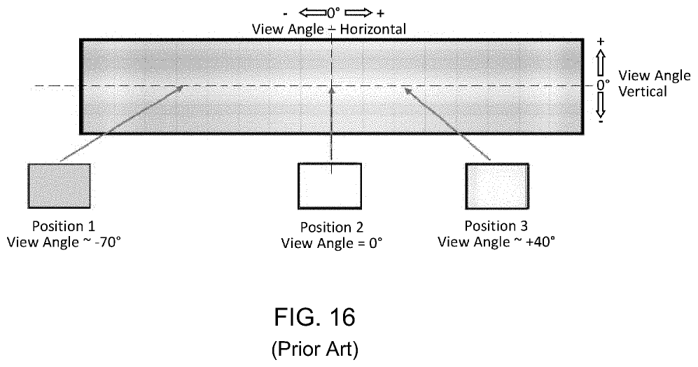

Spacing and sizing of micro-arrays 202 can be based on visual acuity of an observer. Typical visual acuity for adults is 1 arc-minute in size, or approximately 2 pixels per degree as illustrated in FIG. 13. In general, a micro-array size should be selected such that a viewer would not perceive the boundaries of the micro-array. Parameters to be considered in sizing micro-array 202 include an array size which is large enough to yield improvements in durability and robustness, yet small enough for repairability to the array on a PCB.

As reflected in FIG. 13, the distance a viewer is to the screen will have a direct correlation to an ideal array size, however generally the pixel pitch is also chosen based on this distance. In one example, a 100×100 pixel array may be formed according to the present disclosure using an array of micro-arrays 202 with sub-pixels and pixels in as small as a 2×2 array and large as a 16×16 array such that the micro-array size need not exceed 5 mm×5 mm. In the case of a 2×2 micro-array, the footprint of the SMD is four times more robust than a single RGB SMD pixel, yet it is small enough such that it can be replaced to repair the array without being commercially unreasonable. And it is also small enough to be within visual acuity such that an observer will not be able to see a physical pattern or break-up in a very large array (in other words, the “texture” of the front of a very large display will appear uniform).

In one example, the dimensions of micro-array 202 may be approximately 5 mm or less by 5 mm or less. With a 5×5 mm micro-array, individual pixel size may be in the range of about 2×2 mm to about 2.4×2.4 mm in some embodiments. As illustrative examples, white LED 216 may comprise a 6504 Kelvin or 2700 Kelvin LED. A further feature of embodiments disclosed herein, is that each micro-array 202 may be individually encapsulated as shown in FIG. 11. Thus, when an LED fails on one micro-array, only that specific micro-array need be replaced. The replacement micro-array then provides a more uniform appearance with the existing micro-arrays because any variations in encapsulation layers fall within each of the micro-arrays. Also, a single LED failure only requires replacement of a single micro-array, for example just eight LEDs in one embodiment, thus providing much more efficiency and less waste compared to prior designs.

FIG. 14 illustrates an example of a video display or portion of a video display comprised of micro-arrays 202 as disclosed herein. In this embodiment video display 240 comprises an array of tiles 200, with each tile made up of an array of micro-arrays 202. In this example, for illustration purposes only, six tiles 200 each including sixteen micro-arrays 202 are shown. Typical real-world installations will comprise far larger arrays as will be understood by persons skilled in the art.

Further to the array size above, as explained above, embodiments disclosed herein do not utilize simple RGB sets for a pixel. White pixel 216 is added in at least one color temperature in place of an RGB set. In other words, instead of adding another sub-pixel color and attempting to decrease the sub-pixel spacing even more, embodiments of the present disclosure replace three sub-pixels with less components but in a different color. This helps achieve efficiency and also can yield a uniform flat-field white point for a video display.

While RGB and white LED pixels are a common construct and thus used herein for illustration purposes, the principles of the present disclosure are equally applicable to any type of emitter using multi-color pixels, whether RGB LED type emitters, other emitter types (e.g., organic light-emitting diodes (OLED), polymer light-emitting diodes (PLED), active-matrix light-emitting diodes (AMOLED), liquid crystal displays (LCD) or light-emitting electrochemical cells (LEC) as non-limiting examples), or other multi-color pixel combinations (e.g., multi-primary color pixels with four or five colors such as RGBY, RGBM, RGBC or RGBYC as non-limiting examples). The scope of the present disclosure and appended claims is therefore not limited to the illustrative RGB LED examples.

The following numbered subparagraphs define further alternative embodiments, features and advantages of the present disclosure:

1. A light-emitting surface mount device comprising a micro-array of self-emitting pixels including at least one white emitter with a height and width sized at least substantially equal to a combined height and width of a multi-color set of emitters of a neighboring pixel, wherein the micro-array comprises at least 2 horizontal and 2 vertical pixels.

2. The light-emitting surface mount device as described in subparagraph 1 above, wherein at least two said pixels each comprise said one white emitter and at least two said pixels each comprise said multi-color emitters forming a set of sub-pixels.

3. The light-emitting surface mount device as described in subparagraph 1 or 2 above, further comprising a micro-array substrate with each said emitter surface mounted on the micro-array substrate.

4. The light-emitting surface mount device as described in subparagraph 1 or 2 above, further comprising a micro-array substrate with each said multi-color emitters directly bonded thereto and a white emitter substrate with the white emitter directly bonded to the white emitter substrate, and wherein the white emitter substrate is directly bonded to the micro-array substrate.

5. The light-emitting surface mount device as described in any of subparagraphs 1-4 above, wherein the white emitters comprise a white LED and the multi-color emitters comprise a combination of red, green and blue LEDs.

6. A light-emitting surface mount device comprising a 2×2 pixel micro-array with one row consisting of a first pixel formed of one each of a red LED, green LED and blue LED and a second pixel formed of a single white LED and with another row consisting of a first pixel formed of a single white LED and a second pixel formed of one each of a red LED, green LED and blue LED.

7. The light-emitting surface mount device as described in subparagraph 6 above, wherein each said pixel has at least substantially equal total height and width.

8. The light-emitting surface mount device as described in any of subparagraphs 1-5 and 7 above, wherein the total height and width of each pixel varies by not more than about 1%-20% of the total height and width of each other pixel in said micro-array.

9. The light-emitting surface mount device as described in subparagraph 8 above, wherein the total height and width of each pixel varies by not more than about 5%-10% of the total height and width of each other pixel in said micro-array.

10. The light-emitting surface mount device as described in any of subparagraphs 1-9 above, wherein the device is configured as one of a BGA package, a QFN package or a PLCC package.

11. The light-emitting surface mount device as described in any of subparagraphs 1-10 above, wherein the device is no larger than 5 mm×5 mm.

12. The light-emitting surface mount device as described in any of subparagraphs 1-11 above, further comprising a light transmissive encapsulation layer over emitters or LEDs on the micro-array substrate.

13. A light-emitting tile comprising an array of light-emitting surface mount devices as described in any of subparagraphs 1-12 above.

14. A video display wall comprising an array of light-emitting tiles as described in subparagraph 13 above.

15. A method of making a light-emitting micro-array, comprising configuring plural multi-color pixels, each pixel comprising plural different color emitters and having an overall height and width; surface mounting the multi-color pixels to a micro-array substrate; configuring plural white emitters, each said white emitter having an overall height and width substantially the same as the height and width of each said multi-color pixel; and surface mounting the white emitters to the micro-array substrate adjacent the multi-color pixels to form a micro-array of alternating multi-color pixels and white pixels.

16. The method of making a light-emitting micro-array as described in subparagraph 15 above, wherein said surface mounting the white emitters comprise first surface mounting the white emitters to individual substrates and subsequently surface mounting the individual substrates with the white emitters separately on the micro-array substrate.

17. The method of making a light-emitting micro-array as described in either of subparagraphs 15 or 16 above, further comprising encapsulating the emitters in a light transmissive protective layer after surface mounting the emitters to the micro-array substrate.

18. The method of making a light-emitting micro-array as described in any of subparagraphs 1-17 above, wherein the emitters are configured such that the micro-array is no larger than 5 mm×5 mm.

19. A light-emitting device comprising an array of self-emitting pixels, wherein each pixel of the array comprises the same plural different color light emitters; and the different color light emitters of each pixel of the array are arranged in at least one of a different order, different orientation or different alignment relative to the different color light emitters in an at least two adjacent pixels of the array.

20. The light-emitting device as described in subparagraph 19 above, wherein each different color light emitter in each pixel is a non-white emitter.

21. The light-emitting device as described in subparagraph 19 above, wherein the pixel array includes pixels comprising a white emitter and pixels comprising plural non-white color emitters; and each pixel comprising having a white emitter is adjacent to not more than four other pixels in the array having a white emitter.

22. The light-emitting device as described in any of subparagraphs 19-21 above, wherein the different color light emitters are arranged in different orders in the at least two adjacent pixels.

23. The light-emitting device as described in any of subparagraphs 19-21 above, wherein the different color light emitters are arranged in different orientations in the at least two adjacent pixels.

24. The light-emitting device as described in any of subparagraphs 19-21 above, wherein the different color light emitters are arranged in different alignments in the at least two adjacent pixels.

25. The light-emitting device as described in any of subparagraphs 19-24 above, wherein said array comprises a micro-array of self-emitting pixels formed as a surface mount device (SMD).

26. The light-emitting device as described in any of subparagraph 21-25 above, wherein at least two said pixels each comprise said one white emitter and at least two said pixels each comprise said multi-color emitters forming a set of sub-pixels.

27. The light-emitting device as described in subparagraph 25 or 26 above, further comprising a micro-array substrate with each said emitter surface mounted on the micro-array substrate.

28. The light-emitting device as described in subparagraph 25 or 26 above, further comprising a micro-array substrate with each said multi-color emitters directly bonded thereto and a white emitter substrate with the white emitter directly bonded to the white emitter substrate, and wherein the white emitter substrate is directly bonded to the micro-array substrate.

29. The light-emitting device as described in any of subparagraphs 25-28 above, wherein the white emitters comprise a white LED and the multi-color emitters comprise a combination of red, green and blue LEDs.

30. A light-emitting device configured as a surface mount device providing reduced off-axis color skew from specific viewing angles, said device comprising a 2×2 pixel micro-array with one row consisting of a first pixel formed of an ordered sequence of a red LED, a green LED and a blue LED and a second pixel formed of a single white LED, and with another row consisting of a first pixel formed of a single white LED and a second pixel formed of an ordered sequence of a blue LED, a green LED and a red LED.

31. The light-emitting device as described in subparagraph 30 above, wherein each said pixel has at least substantially equal total height and width.

32. The light-emitting device as described in any of subparagraphs 25-30 above, wherein the total height and width of each pixel varies by not more than about 1%-20% of the total height and width of each other pixel in said array.

33. The light-emitting device as described in subparagraph 32 above, wherein the total height and width of each pixel varies by not more than about 5%-10% of the total height and width of each other pixel in said micro-array.

34. The light-emitting device as described in any of subparagraphs 19-33 above, further comprising a light transmissive encapsulation layer over emitters or LEDs mounted on an array substrate.

35. A light-emitting tile comprising an array of light-emitting surface mount devices as described in any of subparagraphs 25-35.

36. A light-emitting array providing off-axis color correction for video wall displays, comprising an SMD having at least four pixel groups arranged in a 2×2 array wherein vertically adjacent pixel groups and horizontally adjacent pixel groups comprise plural individual light emitters positioned relatively differently with respect to one another such that off-axis color skews of the individual light emitters are dispersed between multiple viewing angles to reduce or eliminate cumulative off-axis color skew for said light-emitting display.

37. A video display tile having reduced off-axis color skew, comprising a plurality of light-emitting arrays as described in subparagraph 36 above formed in a tile array, said tile array configured to provide reduced or eliminated color skew when said video display tile is viewed at a specific viewing angle.

38. A method of making a light-emitting device, comprising configuring plural multi-color pixels in two different pixel arrangements, each multi-color pixel comprising plural different color emitters, each different pixel arrangement varying from other pixel arrangements by at least one of emitter color order, color emitter orientation or color emitter alignment; and having an overall height and width; and surface mounting the multi-color pixels in a micro-array to a micro-array substrate wherein each multi-color pixel has a different pixel arrangement from its horizontally adjacent and vertically adjacent multi-color pixels.

39. The method of making a light-emitting device as described in subparagraph 38 above, further comprising configuring plural white emitters; and surface mounting the white emitters to the micro-array substrate adjacent the multi-color pixels to form a micro-array of alternating multi-color pixels and white pixels.

40. The method of making a light-emitting device as described in subparagraph 39 above, wherein said surface mounting the white emitters comprises first surface mounting the white emitters to individual substrates and subsequently surface mounting the individual substrates with the white emitters separately on the micro-array substrate.

41. The method of making a light-emitting device as described in any of subparagraphs 38-40 above, further comprising encapsulating the emitters in a light transmissive protective layer after surface mounting the emitters to the micro-array substrate.

42. The method of making a light-emitting device as described in any of subparagraphs 38-41 above, wherein the emitters are configured such that the micro-array is no larger than 5 mm×5 mm.

43. The method of making a light-emitting device as described in any of subparagraphs 38-42 above, wherein each said multi-color pixel has an overall height and width; and each said white emitter has an overall height and width substantially the same as the height and width of each said multi-color pixel.

44. The devices or methods as described in any of subparagraphs 1-43 above, wherein said emitters comprise at least one of LEDs, OLEDs, PLEDs, AMOLEDs, LCDs, or LECs.

The foregoing has been a detailed description of illustrative embodiments of the disclosure. It is noted that in the present specification and claims appended hereto, conjunctive language such as is used in the phrases “at least one of X, Y and Z” and “one or more of X, Y, and Z,” unless specifically stated or indicated otherwise, shall be taken to mean that each item in the conjunctive list can be present in any number exclusive of every other item in the list or in any number in combination with any or all other item(s) in the conjunctive list, each of which may also be present in any number. Applying this general rule, the conjunctive phrases in the foregoing examples in which the conjunctive list consists of X, Y, and Z shall each encompass: one or more of X; one or more of Y; one or more of Z; one or more of X and one or more of Y; one or more of Y and one or more of Z; one or more of X and one or more of Z; and one or more of X, one or more of Y and one or more of Z.

Various modifications and additions can be made without departing from the spirit and scope of this disclosure. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present disclosure. Additionally, although particular methods herein may be illustrated and/or described as being performed in a specific order, the ordering is highly variable within ordinary skill to achieve aspects of the present disclosure. Accordingly, this description is meant to be taken only by way of example, and not to otherwise limit the scope of this disclosure.

Exemplary embodiments have been disclosed above and illustrated in the accompanying drawings. It will be understood by those skilled in the art that various changes, omissions and additions may be made to that which is specifically disclosed herein without departing from the spirit and scope of the present disclosure.

What is claimed is:

1. A light-emitting surface mount device comprising a micro-array of self-emitting pixels including at least one white emitter with a height and width sized at least substantially equal to a combined height and width of a multi-color set of emitters of a neighboring pixel, wherein the micro-array comprises at least 2 horizontal and 2 vertical pixels.

2. The light-emitting surface mount device of claim 1, wherein at least two said pixels each comprise said one white emitter and at least two said pixels each comprise said multi-color emitters forming a set of sub-pixels.

3. The light-emitting surface mount device of claim 1, further comprising a micro-array substrate with each said emitter surface mounted on the micro-array substrate.

4. The light-emitting surface mount device of claim 1, further comprising a micro-array substrate with each said multi-color emitters directly bonded thereto and a white emitter substrate with the white emitter directly bonded to the white emitter substrate, and wherein the white emitter substrate is directly bonded to the micro-array substrate.

5. The light-emitting surface mount device of claim 1, wherein the white emitters comprise a white LED and the multi-color emitters comprise a combination of red, green and blue LEDs.

6. The light-emitting surface mount device of claim 1, wherein said emitters comprise at least one of LEDs, OLEDs, PLEDs, AMOLEDs, LCDs, or LECs.

7. The light-emitting surface mount device of claim 1, wherein:
each multi-color set of emitters comprises the same plural different color light emitters; and
the different color light emitters of each multi-color set are arranged in at least one of a different order, different orientation or different alignment relative to the different color light emitters at least two adjacent pixels of the array.

8. The light-emitting surface mount device of claim 1, wherein the device is configured as one of a BGA package, a QFN package or a PLCC package.

9. The light-emitting surface mount device of claim 1, wherein the device is no larger than 5 mm×5 mm.

10. The light-emitting surface mount device of claim 1, further comprising a light transmissive encapsulation layer over emitters on the micro-array substrate.

11. A light-emitting tile comprising an array of light-emitting surface mount devices according to claim 1.

12. A video display wall comprising an array of light-emitting tiles according to claim 11.

13. The light-emitting surface mount device of claim 1, wherein the micro-array comprises a 2×2 pixel micro-array with one row consisting of a first pixel formed of one each of a red LED, green LED and blue LED and a second pixel formed of a single white LED and with another row consisting of a first pixel formed of a single white LED and a second pixel formed of one each of a red LED, green LED and blue LED.

14. The light-emitting surface mount device of claim 13, wherein each said pixel has at least substantially equal total height and width.

15. The light-emitting surface mount device of claim 13, wherein a total height and width of each pixel varies by not more than about 1%-20% of the total height and width of each other pixel in said micro-array.

16. A method of making a light-emitting micro-array, comprising:
configuring plural multi-color pixels, each pixel comprising plural different color emitters and having an overall height and width;
surface mounting the multi-color pixels to a micro-array substrate;
configuring plural white emitters, each said white emitter having an overall height and width substantially the same as the height and width of each said multi-color pixel; and
surface mounting the white emitters to the micro-array substrate adjacent the multi-color pixels to form a micro-array of alternating multi-color pixels and white pixels.

17. The method of making a light-emitting micro-array according to claim 16, wherein said surface mounting the white emitters comprises first surface mounting the white emitters to individual substrates and subsequently surface mounting the individual substrates with the white emitters separately on the micro-array substrate.

18. The method of claim 16, wherein said configuring of plural multi-color pixels further comprises configuring plural multi-color pixels in two different pixel arrangements, each multi-color pixel comprising plural different color emitters, each different pixel arrangement varying from other pixel arrangements by at least one of emitter color order, color emitter orientation or color emitter alignment; and having an overall height and width; and said surface mounting the multi-color pixels comprises surface mounting the multi-color pixels to the micro-array substrate wherein each multi-color pixel has a different pixel arrangement from its horizontally adjacent and vertically adjacent multi-color pixels.

19. A light-emitting device comprising an array of self-emitting pixels, wherein:
each pixel of the array comprises the same plural different color light emitters; and
the different color light emitters of each pixel of the array are arranged in at least one of a different order, different orientation or different alignment relative to the different color light emitters in an at least two adjacent pixels of the array.

20. The light-emitting device of claim 19, wherein each different color light emitter in each pixel is a non-white emitter.

21. The light-emitting device of claim 19, wherein:
the pixel array includes pixels comprising a white emitter and pixels comprising plural non-white color emitters; and
each pixel comprising having a white emitter is adjacent to not more than four other pixels in the array having a white emitter.

22. The light-emitting device of claim 19, wherein the different color light emitters are arranged in different orders in the at least two adjacent pixels.

23. The light-emitting device of claim 19, wherein the different color light emitters are arranged in different orientations in the at least two adjacent pixels.

24. The light-emitting device of claim 21, wherein the different color light emitters are arranged in different alignments in the at least two adjacent pixels.

25. The light-emitting device of claim 19, wherein said array comprises a micro-array of self-emitting pixels formed as a surface mount device (SMD).

26. The light-emitting device of claim 21, wherein at least two said pixels each comprise said one white emitter and at least two said pixels each comprise said multi-color emitters forming a set of sub-pixels.

27. A light-emitting tile comprising an array of light-emitting surface mount devices according to claim 19.

28. A light-emitting device configured as a surface mount device providing reduced off-axis color skew from specific viewing angles, said device comprising a 2×2 pixel micro-array with one row consisting of a first pixel formed of an ordered sequence of a red LED, a green LED and a blue LED and a second pixel formed of a single white LED, and with another row consisting of a first pixel formed of a single white LED and a second pixel formed of an ordered sequence of a blue LED, a green LED and a red LED.

29. The light-emitting device of claim 28, wherein each said pixel has at least substantially equal total height and width.
